(19) United States
(12) Patent Application Publication
(10) Pub. No.: US 2025/0216792 A1
(43) Pub. Date: Jul. 3, 2025

(54) METHOD FOR OPERATING A PROJECTION EXPOSURE SYSTEM

(71) Applicant: Carl Zeiss SMT GmbH, Oberkochen (DE)

(72) Inventors: Joerg ZIMMERMANN, Aalen (DE); Toralf GRUNER, Aalen (DE); Johannes RUOFF, Cupertino, CA (US)

(21) Appl. No.: 19/082,444

(22) Filed: Mar. 18, 2025

Related U.S. Application Data
(63) Continuation of application No. PCT/EP2023/075900, filed on Sep. 20, 2023.

(30) Foreign Application Priority Data
Sep. 23, 2022 (DE) 10 2022 210 088.3

(51) Int. Cl. G03F 7/00

(52) U.S. Cl. CPC G03F 7/70116; G03F 7/70033; G03F 7/702; G03F 7/70233

(57) ABSTRACT

In a method for operating a microlithographic projection exposure apparatus, a mask is repeatedly exposed to an exposure radiation provided by an illumination system, and mask structures are imaged in the process on in each case one of a multiplicity of fields of a plurality of semiconductor substrates. During a period in which the repeated exposure of the mask takes place, the illumination system is used successively in at least two different illumination settings of the illumination system, in which different illumination distributions of the exposure radiation are present in a pupil plane of the illumination system, with a pupil surface illuminated in the first illumination setting having no overlap or an overlap of at most 90% of the respective illuminated pupil surface with a pupil surface illuminated in the second illumination setting, with the mask being fully exposed at least once in each of the different illumination settings.

### CROSS-REFERENCE TO RELATED APPLICATIONS

The present application is a continuation of, and claims benefit under 35 USC 120 to, international application No. PCT/EP2023/075900, filed Sep. 20, 2023, which claims benefit under 35 USC 119 of German Application No. 10 2022 210 088.3, filed Sep. 23, 2022. The entire disclosure of each of these applications is incorporated by reference herein.

### FIELD

The disclosure relates to a method of operating a microlithographic projection exposure apparatus.

### BACKGROUND

These days, lithographic projection exposure methods are predominantly used for producing semiconductor devices and other finely structured components. In the process, a pattern arranged on a mask or a reticle is positioned in a projection exposure apparatus between an illumination system and a projection lens in the region of a mask plane or object plane of the projection lens and is illuminated with an illumination radiation shaped by the illumination system. The radiation modified by the pattern passes through the projection lens, whereby the pattern is imaged onto a radiation-sensitive layer of a semiconductor substrate.

Exposure is increasingly optimized specifically for specific chip-layer structures, which can result in fragmented and sometimes highly localized illumination distributions in the pupil plane of the illumination system when compared to conventional shapes such as e.g. annular, dipole, quasar. An aim here is to obtain a contrast of the imaged structures that is as high as reasonably possible, especially of the structures relevant to the function of the semiconductor component. For example, these may have relatively small dimensions or relatively small distances from neighboring structures. An aim is to achieve a relatively high yield regardless of inaccuracies in the exposure dose and focal position, as can be observed in the real manufacturing process.

What is known as a lithographic process window is often used in order to quantify such relationships. With regard to the inaccuracy of a lithographic parameter, for instance a predetermined structure dimension inaccuracy, e.g. 10% line width, the dose error that precisely leads to this deviation of the lithographic parameter is determined for a certain focus error in the lithographic process window. As a rule, different illumination distributions lead to varying process windows. Furthermore, a high insensitivity to focus errors often leads to a higher sensitivity to dose errors, and vice versa. Depending on the choice of illumination, the emphasis may be placed differently on one of the two influencing factors.

On account of the localized illumination peaks, high-stress regions can be now created on optical surfaces with temperature peaks. Accordingly, there can be a conflict between illumination optimized for a high contrast on the one hand and, on the other hand, high thermally induced aberrations, which in turn may reduce the yield, be it through positioning errors (“overlay”) or through focus effects that in turn reduce contrast.

### SUMMARY

The disclosure seeks to provide a method of operating a microlithographic projection exposure apparatus, whereby known issues may be solved and, for example, the projection exposure apparatus may be operated over a relatively long period of time without significant losses in the lithographic process window.

According to the disclosure, issues may for example be addressed by way of a method for operating a microlithographic projection exposure apparatus, wherein a mask is repeatedly exposed to an exposure radiation provided by an illumination system, and mask structures are imaged in the process on in each case one of a multiplicity of fields of a plurality of semiconductor substrates. During a period in which the repeated exposure of the mask takes place, the illumination system is used successively in at least two different illumination settings of the illumination system, in which different illumination distributions of the exposure radiation are present in a pupil plane of the illumination system, such that a pupil surface illuminated in the first illumination setting has no overlap or an overlap of a maximum of 90% of the respective illuminated pupil surface with a pupil surface illuminated in the second illumination setting. Furthermore, the mask is fully exposed at least once in each of the two different illumination settings. In other words, at least one complete mask scan is performed in each of the illumination settings in the event of the projection exposure apparatus being embodied as a scanner. According to an embodiment, the mask is fully exposed multiple times in each of the two different illumination settings, for example exposed at least ten times, at least 100 times or at least 1000 times, without an intervening change of the illumination setting.

According to an embodiment, the different illumination settings are each maintained at least over a period of time that is used for a two-time exposure of the mask. According to an embodiment, the different illumination settings are each maintained over at least a period of time that is used for at least a ten-time exposure of the mask. According to an embodiment, the different illumination settings are each maintained over at least a period of time that is used for the complete exposure of a semiconductor substrate, for example for the exposure of a plurality of semiconductor substrates, for example for the exposure of at least ten semiconductor substrates. According to an embodiment, the different illumination settings are each maintained over at least a period of time that is used for the exposure of at least one batch of semiconductor substrates, for example for the exposure of a plurality of batches of semiconductor substrates, for example for the exposure of at least ten batches of semiconductor substrates. For example, a batch may comprise at least twenty semiconductor wafers, for example at least twenty-five semiconductor wafers.

According to different embodiments, the overlap may be a maximum of 80%, a maximum of 50%, a maximum of 20% or a maximum of 10%. This means that a pupil section illuminated in the pupil plane or a totality of a plurality of pupil sections illuminated in the pupil plane, i.e. the surfaces illuminated in the pupil plane, do not overlap at all or have an overlap of a maximum of 90% or one of the other aforementioned maximum values.

In other words, the pupil surface illuminated in the first illumination setting has an overlap of a maximum of 90% or any other of the aforementioned values of the respective illuminated pupil surface with the pupil surface illuminated in the second illumination setting, wherein the overlap may also be 0%.

Because the mask in a specific illumination setting is exposed by the corresponding illumination radiation in each case, the overlap should not be understood to mean that the relevant surface portion or portions are illuminated at the same time. Instead, the overlap relates to one or more surface sections that are illuminated by the relevant illumination setting at different times.

That is to say, a pupil surface that is illuminated in a first illumination setting and also referred to as first surface differs from a pupil surface that is illuminated in the second illumination setting and also referred to as second surface to the extent that the two surfaces in each case correspond in terms of a portion of a maximum of 90% of the relevant total area or do not correspond to one another at all, i.e. the illuminated surfaces differ by more than 10% from one another. This should be understood to mean that the portion of the first surface which has a correspondence in the second surface, i.e. corresponds to the relevant portion of the second surface, makes up 90% or less of the total area of the first surface. This also applies conversely to the portion of the second surface; the latter makes up 90% or less of the total area of the second surface. In analogous fashion, when more than two different illumination settings are used, the portions of the surfaces illuminated in the various illumination settings which correspond to one another in all illumination settings in each case make up a maximum of 90% of the overall area of the relevant surface.

A pupil plane of the illumination system is characterized in that the local intensity distribution of the illumination radiation that converges on a specific field point on the mask corresponds in the pupil plane to the angle-resolved intensity distribution at this field point.

The successive use according to the disclosure of the illumination system in the above-described at least two different illumination settings of the illumination system can prevent excessive formation of wavefront aberrations on account of local heating in optical elements of the projection exposure apparatus, for example in optical elements of the projection lens. As a result of using the different illumination settings, it is possible to change the radiation distribution on the optical elements before the occurrence of local heating relevant to possible wavefront errors.

During the repeated exposure of the mask according to one embodiment, there is a time interval of less than 200 minutes, for example less than 60 minutes or less than 20 minutes, between switches between the two different illumination settings.

According to an embodiment, the pupil surfaces illuminated in the different illumination settings each have a plurality of surface portions that are separated from one another.

According to an embodiment, there a switch from a first of the two different illumination settings with a first configuration of surface portions in the pupil plane to the second illumination setting with a second configuration of surface portions in the pupil plane by virtue of in each case incrementally switching over an illumination of a surface portion or a subgroup of the surface portions of the first configuration to an illumination of another surface portion or another subgroup of the surface portions of the second configuration.

According to an embodiment, there is a switch from a first of the two different illumination settings to the second illumination setting by virtue of the first illumination distribution assigned to the first illumination setting being incrementally adapted to the second illumination distribution assigned to the second illumination setting. This procedure may also be referred to as morphing.

According to an embodiment, the illumination system comprises a pupil facet optical unit with a plurality of individual optical units arranged in a pupil plane of the illumination system and a field facet optical unit arranged in a plane conjugate to the mask plane, with the field facet optical unit comprising a plurality of further individual optical units, which are configured to irradiate the individual optical units of the pupil facet optical unit for the respective formation of a radiation channel of the beam path of the illumination radiation, with there being a switch between different radiation channels by successively moving one or more of the individual optical units of the field facet optical unit during the incremental adaptation of the first illumination distribution to the second illumination distribution. That is to say, the exposure radiation previously guided in one radiation channel is subsequently guided in another radiation channel.

According to an embodiment, the illumination distributions in the pupil plane present for the different illumination settings are each assigned to at least one uniform field point in a mask plane of the projection exposure apparatus. In other words, the first illumination distribution assigned to the first illumination setting is assigned to the same field point or the same plurality of field points as the second illumination distribution assigned to the second illumination setting.

According to an embodiment, in the respective illumination setting, the relevant illumination distribution or an illumination distribution with a deviation of no more than 5%, for example no more than 1%, is assigned to a plurality of field points in a mask plane of the projection exposure apparatus. In other words, the illumination distribution mentioned in the respective illumination setting is present in the pupil plane for a plurality of field points in the mask plane of the projection exposure apparatus, with the illumination distribution still being referred to as the same illumination distribution even in the event of a pupil surface deviating by a maximum of 5%.

According to an embodiment, the plurality of field points form a contiguous region in the mask plane. The pupil surface illuminated in the pupil plane in the presence of one of the illumination distributions is not a contiguous surface in this embodiment but has a plurality of separate surface portions. According to an alternative embodiment, at least one of the pupil surfaces illuminated in the various illumination settings is a contiguous surface.

According to an embodiment, in each of the illumination settings, an area of a lithographic process window for imaging a predetermined type of mask structures, which does not take into account thermal wavefront aberrations that are due to thermal heating effects in a projection lens of the projection exposure apparatus caused by the exposure radiation, is no more than 20% smaller, for example no more than 10% smaller, than the area of an assigned optimized lithographic process window, which is optimized for imaging the predetermined type of mask structures by varying the illumination setting.

For example, such a lithographic process window is formed by a diagram in which an area is surrounded by a curve and two coordinate axes, plotted on which are dose variation of the exposure radiation and defocus of the imaging, with a lithographic parameter at points represented by the area being located within a tolerance range about a target value. For example, the lithographic parameter may be a variation of a critical dimension, for instance a line width in the photoresist (also referred to as CD variation), of a mask structure imaged onto the semiconductor substrate using the relevant illumination setting. Alternatively, a side angle of an imaged structure in the photoresist or lateral displacements of resist structures (also referred to as “overlay”), for example, may also serve as lithographic parameters.

The aerial image of the projection exposure apparatus created in the image plane, with a resist threshold being taken into account, may serve for the computational estimate of the line width. A resist threshold should be understood to mean an intensity threshold, above which the photoresist is exposed. To determine a process window experimentally, it is possible to evaluate a focus-dose matrix (also known as an FEM matrix-focus exposure matrix) on a semiconductor substrate coated with photoresist.

For example, the lithographic process window optimized for imaging the predetermined type of mask structures should be understood to mean the process window that arises by modifying the illumination setting without wavefront aberrations being taken into account, the area of the process window being maximal and the shape of the process window not undershooting certain desired minimum properties. For example, such a minimum desired property should be understood to mean the aspect ratio of the process window, for instance measured using the ratio of the axis portions of the process window. The axis portions should not deviate too much from one another, i.e. the play in the focus variation should not be increased too much to the detriment of the play in the dose variation, and vice versa.

According to an embodiment, in one of the illumination settings, the area of the lithographic process window is optimized for imaging a predetermined type of mask structures without taking into account the thermal wavefront aberrations.

According to an embodiment, in at least one of the illumination settings, the area of the lithographic process window for imaging a predetermined type of mask structures without taking into account the thermal wavefront aberrations is at least 5% smaller than the area of the assigned optimized process window.

According to an embodiment, in the configuration of the mask structures and the illumination distribution of at least one of the illumination settings, thermal heating effects in a projection lens of the projection exposure apparatus, which occur within a period of time in which the mask is exposed with the respective illumination setting, i.e. the period of time that elapses before a change between the exposure settings, are taken into account.

According to an embodiment, the projection exposure apparatus is designed for an operating wavelength in the EUV wavelength range. Operation of a projection exposure apparatus in the EUV wavelength range means managing without refractive media, which generally can no longer be used meaningfully at this wavelength, and the transition to pure mirror systems which operate either with virtually normal incidence or in grazing fashion. With normal incidence, approximately a third of the incident light is absorbed on each mirror (depending on the specific incidence angle spectrum); with grazing incidence, typical absorption values are a quarter or a fifth. In refractive media with an antireflective layer, the absorbed intensity, for comparison, is of the order of parts per thousand. This helps explain considerably greater temperature changes in EUV optical units in comparison with systems operated with UV light.

Because temperature gradients are translated into surface defects on account of the coefficient of thermal expansion, their consequence, precisely in mirrors, can be considerable optical aberrations that cause images to deteriorate in relation to the used wavelength. Accordingly, EUV mirrors are often manufactured from material with a relatively low coefficient of thermal expansion, e.g. Zerodur or ULE (“ultra-low expansion” material). These materials react nonlinearly to temperature changes. In the vicinity of a zero-crossing temperature, which often corresponds to the expected mean mirror temperature, the materials exhibit a relatively small thermally induced change in the volume. However, if the local temperature deviates significantly from this optimal zero-crossing temperature, changes in volume and, as a result thereof, surface deformations and wavefront disturbances increase disproportionately. Local peaks in the illumination intensity, which lead to hot spots, therefore may be of interest.

The features specified in relation to the aforementioned embodiments, exemplary embodiments and embodiment variants, etc., of the method according to the disclosure are explained in the description of the figures and the claims. The individual features may be implemented, either separately or in combination, as embodiments of the disclosure. Furthermore, they may describe embodiments which are independently protectable and protection for which is claimed only during or after pendency of the application, as the case may be.

### BRIEF DESCRIPTION OF THE DRAWINGS

The aforementioned features and further features of the disclosure will be illustrated in the following detailed description of exemplary embodiments according to the disclosure or of embodiments with reference to the attached schematic drawings, in which:

FIG. 1 shows a sectional view of an embodiment of a microlithographic projection exposure apparatus having an illumination system comprising a field facet mirror and a pupil facet mirror;

FIG. 2 shows a plan view of the field facet mirror and the pupil facet mirror;

FIG. 3 shows a plan view of a first embodiment of the pupil facet mirror with two different illumination distributions;

FIG. 4 shows a plan view of the pupil facet mirror with the two different illumination distributions as per FIG. 3 and further intermediate illumination distributions;

FIG. 5 shows a plan view of an embodiment of the pupil facet mirror with two different illumination distributions; and

FIG. 6 shows lithographic process windows for a predetermined mask structure under different illumination settings.

### DETAILED DESCRIPTION

In the exemplary embodiments or embodiments or embodiment variants described below, elements which are functionally or structurally similar to one another are provided with the same or similar reference signs as far as reasonably possible. Therefore, for understanding the features of the individual elements of a specific exemplary embodiment, reference should be made to the description of other exemplary embodiments or the general description of the disclosure.

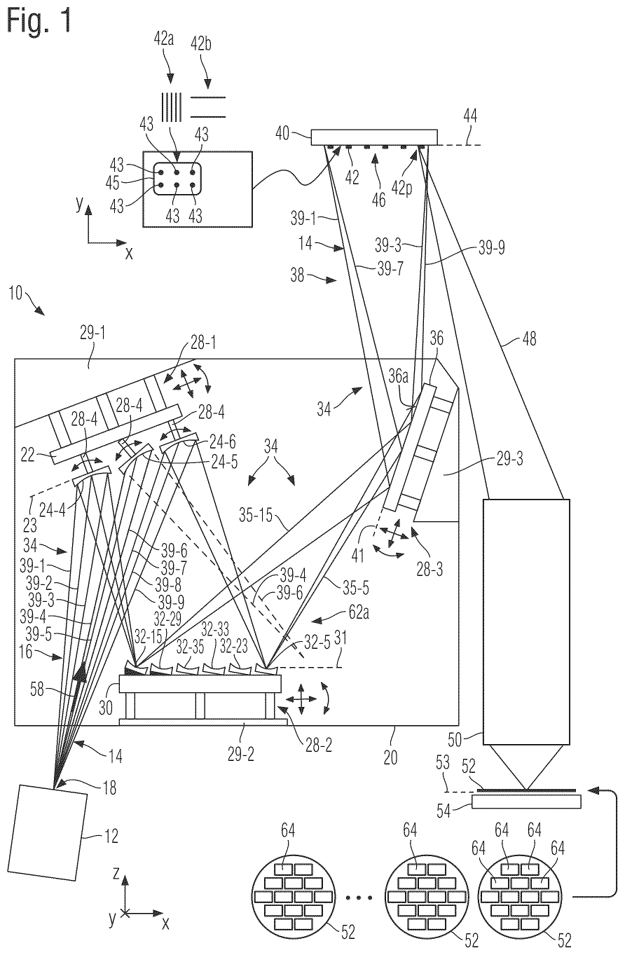

In order to facilitate the description, a Cartesian xyz-coordinate system is indicated in the drawing, from which system the respective positional relationship of the components illustrated in the figures is evident. In FIG. 1, the y-direction runs perpendicularly to the plane of the drawing into the plane, the x-direction runs toward the right, and the z-direction runs upward.

FIG. 1 shows a schematic view of an embodiment of a microlithographic projection exposure apparatus 10, which is configured to produce microstructured components, e.g. components containing integrated circuits. The projection exposure apparatus 10 serves to transfer mask structures 42, which are arranged on a mask 40 in the form of a reticle, to a photosensitive layer in the form of a lithographic resist of a semiconductor substrate 52, which is arranged in an image plane 53 of the projection exposure apparatus 10, via a projection lens 50. Examples of such mask structures 42 comprise dense lines denoted by reference sign 42a and interspaces and isolated lines denoted by reference sign 42b. The exposed points on the surface of the mask 40 are referred to as field points 43 in the mask plane 44. As a rule, what are known as wafers made of silicon or any other semiconductor material are used as semiconductor substrate 52.

When transferring the mask structures 42 to the photosensitive layer, the mask structures 42 arranged in an imaging field on the mask 40 are imaged onto a field 64 of the semiconductor substrate 52. In successive exposures of the mask 40, the semiconductor substrate 52 is in each case displaced in terms of its xy-position such that the mask structures 42 are imaged onto different fields 64 of the semiconductor substrate 52. Once all fields 64 of the semiconductor substrate 52 arranged on the substrate stage 54 have been exposed, the semiconductor substrate 52 is replaced by a new semiconductor substrate 52, whereupon all fields 64 on the latter are exposed in turn. This is implemented for a multiplicity of semiconductor substrates 52, as illustrated in the bottom right portion of FIG. 1. In other words, the mask 40 is exposed repeatedly by the exposure radiation, with the mask structures 42 of the mask 40 being imaged onto in each case one of a multiplicity of fields 64 of a plurality of semiconductor substrates 52.

In FIG. 1, imaging the mask 40 is merely depicted on the basis of the imaging of an exemplary point 42P of the mask surface to be imaged onto one of the semiconductor substrates 52. To this end, an imaging beam path 48 relating to the point 42P is plotted through the projection lens 50. Other points on the mask surface are imaged onto the semiconductor substrate 52 by way of corresponding imaging beam paths. Thus, for example, points arranged in the left-hand portion of the mask 42 are also imaged onto the semiconductor substrate 52.

For this purpose, the projection exposure apparatus 10 according to FIG. 1 contains an exposure radiation source 12, an illumination system 20, a reticle stage (not depicted in the drawing) for mounting and positioning the mask 40, the aforementioned projection lens 50 in the form of an imaging optical system with a plurality of optical elements for imaging the mask structures 42 onto the semiconductor substrate 52 in an exposure operation of the projection exposure apparatus 10 and a substrate stage 54 for mounting and positioning the semiconductor substrate 52. Imaging the mask structures 42 onto the semiconductor substrate 52 is implemented via the aforementioned imaging beam path 48, which passes through the projection lens 50.

During the exposure operation, the illumination system 20 serves to radiate an exposure radiation 14 with a suitable angular distribution onto an object field of the mask 40 arranged in a mask plane 44. In other words: on the object field, the illumination system 20 creates an illumination field 46 in the form of an intensity distribution of the exposure radiation 14 in the mask plane 44. In FIG. 1, the exposure radiation 14 is illustrated on the basis of a multiplicity of individual rays 39. These comprise individual rays 39-1, 39-2 and 39-3 radiated onto a mirror element 24-4, individual rays 39-4, 39-5 and 39-6 radiated onto a mirror element 24-5 and individual rays 39-7, 39-8 and 39-9 radiated onto a mirror element 24-6.

To create the illumination field 46, the illumination system 20 in the shown embodiment comprises three optical modules. The optical modules comprise a field facet optical unit in the form of a field facet mirror 22 comprising the aforementioned mirror elements 24, a pupil facet optical unit in the form of a pupil facet mirror 30 and what is known as a G-mirror 36. The field facet mirror 22 is arranged substantially parallel to or along a system surface, conjugate to the mask plane 44, in the form of a field plane 23. The pupil facet mirror 30 is arranged substantially parallel to or along a system surface in the form of a pupil plane 31 of the illumination system 20. The G-mirror 36 comprises a mirror surface 36a that is arranged parallel to or along a system surface 41.

In this document, a system surface of the illumination system 20 should be understood to mean a surface, parallel to which or along which an optical module, for instance the field facet mirror 22, the pupil facet mirror 30 or the G-mirror 36, is arranged. In the case in which an optical module is a reflective optical module with a plurality of mirror elements, like the present optical modules, the system surface extends substantially parallel to or along the reflective surfaces of the mirror elements. In embodiments not depicted in the drawing, the optical modules may also contain lens elements; in this case, the system surfaces extend substantially parallel to or along respective front or back sides of the lens elements. Furthermore, the optical modules may also in each case contain merely one mirror element or merely one lens element.

The exposure radiation 14 is created by the aforementioned exposure radiation source 12, which is embodied as a point radiation source, and is radiated in the form of a divergent input wave 16, which emanates from a source point 18 and propagates in an incoming radiation direction 58, onto the field facet mirror 22. Depending on the design of the projection exposure apparatus 10, the wavelength of the exposure radiation 14 may be in the UV wavelength range, e.g. at approximately 365 nm, approximately 248 nm or approximately 193 nm, or in the EUV wavelength range, i.e. in a wavelength range of less than 100 nm, for example at a wavelength of approximately 13.5 or approximately 6.8 nm. In the case illustrated here, the illumination radiation 14 is EUV radiation; thus, all optical elements of the exposure beam path of the projection exposure apparatus 10 are embodied as mirrors.

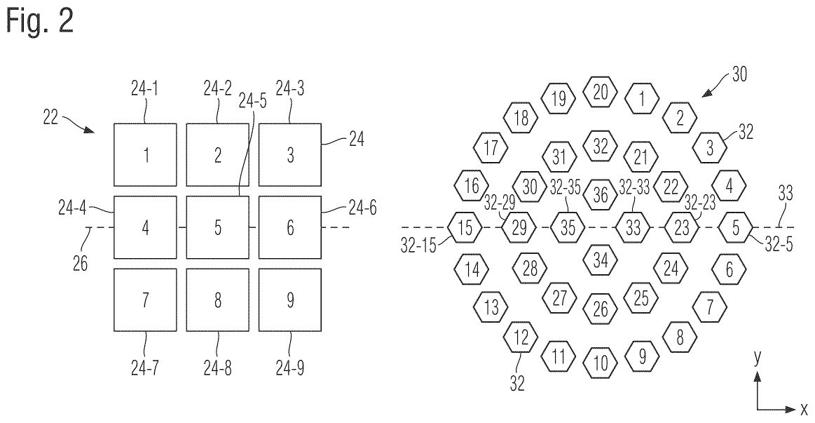

The field facet mirror 22 comprises a two-dimensional grid of individual optical units in the form of mirror elements 24. The individual optical units may also be designed as lens elements in alternative embodiments for illumination radiation in the UV wavelength range. The left-hand region of FIG. 2 depicts the field facet mirror 22 according to FIG. 1 in a plan view with an exemplary embodiment of the grid with three-by-three mirror elements 24. These are numbered consecutively by numerals 1 to 9. In further embodiments, the field facet mirror 22 may comprise fewer, or else more, mirror elements 24. The respective shape of the mirror elements 24 is adapted to the shape of the illumination field 46 in the mask plane 44 and is therefore rectangular or sickle shaped.

Here, in the case of a projection exposure apparatus 10 embodied as a step and scan exposure apparatus, the illumination field 46 is understood to mean that area on the mask 40 which is illuminated by the scanner slot at a given point in time. The two-dimensional grid of the mirror elements 24 is orthogonal in the embodiment shown. FIG. 1 depicts the field facet mirror 22 in sectional view along a sectional line 26 from FIG. 2. The aforementioned mirror elements 24-4 to 24-6 are arranged along this sectional line 26. Each of the mirror elements 24 of the field facet mirror 22 is mounted individually adjustably via a respective manipulator 28-4 in the form of an actuator. For example, an individual tilt of the respective mirror element 24 about two mutually orthogonal tilt axes is possible. The manipulators 28-4 embodied as actuators may be controlled centrally.

The pupil facet mirror 30 also comprises a two-dimensional arrangement of individual optical units in the form of mirror elements, which are denoted by reference sign 32. The right-hand region of FIG. 2 depicts the pupil facet mirror 30 in a plan view with an exemplary embodiment of an arrangement of thirty-six mirror elements 32. These are numbered consecutively by numerals 1 to 36. In further embodiments, the pupil facet mirror 30 may comprise fewer, or else more, for example even several hundred or several thousand, mirror elements 32.

According to one embodiment, the field facet mirror 22 and the pupil facet mirror 30 together comprise several tens of thousands of mirror elements or more than one hundred thousand mirror elements. In this case, the facet mirrors 22 and 30 may each take the form of a MEMS mirror grid, wherein the individual mirror elements may be grouped into functional units according to one embodiment variant. In this case, the mirror elements combined in a functional unit may for example in each case adopt the function of one of the mirror elements 24 or 32 according to FIG. 2.

In the embodiment shown in FIG. 2, the number of mirror elements 32 in the pupil facet mirror 30 is four times the number of mirror elements 24 in the field facet mirror 22. In other embodiments, the number of mirror elements 32 in the pupil facet mirror 30 may also be comparatively larger or smaller. For example, the number of mirror elements 32 in the pupil facet mirror 30 may be greater than or less than four times the number of the mirror elements 24 in the field facet mirror 22. In the embodiment shown, the mirror elements 32 are hexagonal and arranged along concentric circles, and so the overall arrangement is similar to that of a honeycomb.

FIG. 1 depicts the pupil facet mirror 30 in sectional view along a sectional line 33 from FIG. 2. Six mirror elements 32-15, 32-29, 32-35, 32-33, 32-23 and 32-5 are arranged along this sectional line 33. The structure of the facet mirrors 22 and 30 may for example also take the form of one of the variants described in US 2011/0001947 A1.

Each of the thirty-six mirror elements 32-1 to 32-36 of the pupil facet mirror 30 is assigned a respective radiation channel 35-1 to 35-36, which extends from the mirror element 24-1 to 24-9, assigned to the corresponding mirror element 32, of the field facet mirror 22 via the corresponding mirror element 32 and via the G-mirror 36 explained in detail below to the mask plane 44.

To activate corresponding radiation channels 35-1 to 35-36, the corresponding mirror elements 32-1 to 32-36 of the pupil facet mirror 30 are irradiated by way of a suitable tilt of the mirror elements 24-1 to 24-9 of the field facet mirror 22. Since the mirror elements 24-1 to 24-9 can each irradiate only one of the mirror elements 32-1 to 32-36, it is possible to activate a maximum of nine of the radiation channels 35-1 to 35-36 at the same time.

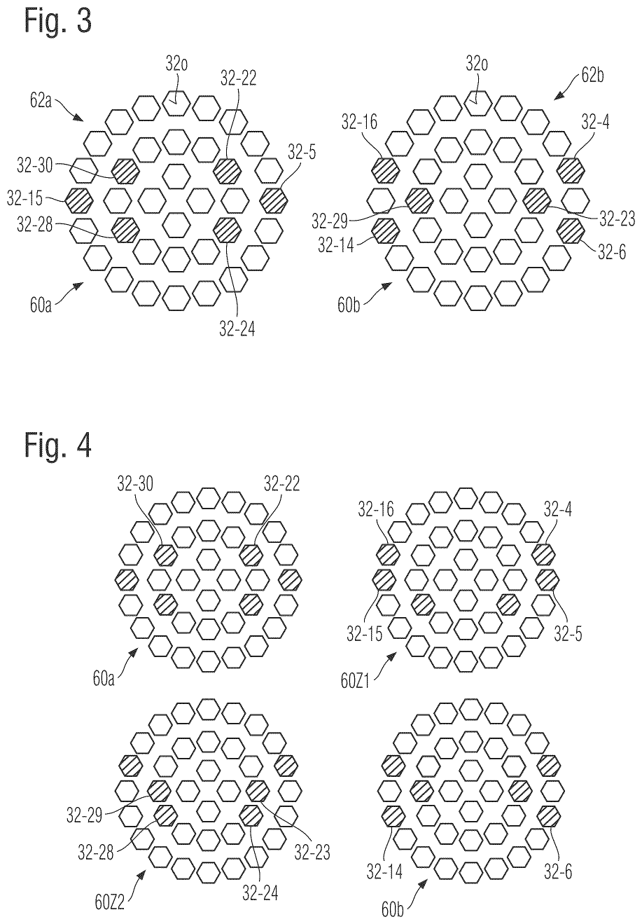

In the illumination setting 62a of the illumination system 20 shown in FIG. 1, the mask 40 is illuminated with an angular distribution that corresponds to the illumination distribution 60a in the pupil plane 31 depicted on the left-hand side in FIG. 3. To this end, the exposure radiation 14 only irradiates the illumination field 46 via the mirror elements 32-15, 32-30, 32-28, 32-22, 32-24 and 32-5, i.e. only the radiation channels 35-15, 35-30, 35-28, 35-22, 32-24 and 35-5 are active. Hence, only the mirror elements 32-15 and 32-5 of the pupil facet mirror 30 are active in the sectional view of FIG. 1, i.e. only these mirror elements are irradiated by the respectively assigned mirror elements 24 of the field facet mirror 22 in order to form the radiation channels 35-15 and 35-5 that in each case illuminate the entire illumination field 46.

In this document, the illumination distribution 60a in the pupil plane is also referred to as illuminated pupil surface. The latter consists of the totality of the surfaces 32o of the mirror elements 32-15, 32-30, 32-28, 32-22, 32-24 and 32-5. Each of the surfaces 32o represents a delineated surface portion. In the illustrated exemplary embodiment, these surface portions have a hexagonal shape and are separated from one another in each case by a distance.

In order to form the illumination distribution 60a, the mirror element 32-30 of the pupil facet mirror 30 may be irradiated by the mirror element 24-1 of the field facet mirror 22, and the mirror element 32-15, the mirror element 32-28, the mirror element 32-22, the mirror element 32-5 and the mirror element 32-24 may be irradiated by, respectively, the mirror element 24-4, the mirror element 24-7, the mirror element 24-3, the mirror element 24-6 and the mirror element 24-9. The mirror elements 24-2, 24-5 and 24-8 of the field facet mirror 22 are tilted such that the radiation portion of the input wave 16 incident thereon is not incident on the pupil facet mirror 30.

In the illustrated embodiment, the radiation channels 35-30, 35-22, 35-15, 35-5, 35-28 and 35-24 that emanate from the mirror elements 24-1, 24-3, 24-4, 24-6, 24-7 and 24-9 of the field facet mirror 22 and lead to the mask plane 44 via the pupil facet mirror 30 and the G-mirror 36 form an illumination beam path 34 in the illumination system 20. The G-mirror 36 is a mirror operated with grazing incidence and also referred to as a grazing incidence mirror. The wave from the G-mirror 36 irradiating the mask plane 44 is also referred to as output wave 38 of the illumination system 20.

The illumination beam path 34 comprises a multiplicity of individual rays 39. In this context, an individual ray is understood to be a light path situated within the beam path and represented on the basis of a line. Each of the radiation channels active in the setting depicted in FIG. 1 comprises a bundle of individual rays.

Of this bundle, only a few individual rays are depicted in FIG. 1 by way of example. These are the individual rays 39-1 and 39-3 delimiting the radiation channel 35-15 in the plane of the drawing and the individual ray 39-2 running centrally in the radiation channel 35-15. Furthermore, the individual rays 39-4 and 39-6 delimiting the radiation beam irradiating the mirror element 24-5 and the individual ray 39-5 running centrally in this radiation bundle are depicted. Furthermore, the individual rays 39-7 and 39-9 delimiting the radiation channel 35-5 in the plane of the drawing and the individual ray 39-8 running centrally in the radiation channel 35-5 are depicted. To simplify the illustration, the central individual rays 39-2, 39-5 and 39-8, which run from the illumination radiation source 12 to the mask plane 44, are only depicted in the region between the illumination radiation source 12 and the field facet mirror 22 in FIG. 1.

Using a manipulator 28-1, the field facet mirror 22 as a whole is mounted so as to be adjustable in terms of its position vis-à-vis a frame element 29-1 of the illumination system 20. In this case, the manipulator 28-1 is configured as an adjustment device that allows a plurality of rigid body degrees of freedom, for example all six rigid body degrees of freedom, i.e. translations and rotations with respect to all three orthogonal spatial directions in each case, to be set, as indicated in FIG. 1 on the basis of arrows. In this context, the adjustment device may be manually adjustable or else comprise electrically controllable actuators. Furthermore, the individual mirror elements 24-1 to 24-9 of the field facet mirror 22 are mounted to be individually adjustable by way of the manipulators 28-4. According to the described embodiment, each of the mirror elements 24 is tiltable about two mutually orthogonal tilt axes.

Using a corresponding manipulator 28-2 or 28-3, both the pupil facet mirror 30 as a whole and the G-mirror 36 are mounted so as to be adjustable in terms of their position vis-à-vis a frame element 29-2 or 29-3 of the illumination system 20. In a manner analogous to the manipulator 28-1 assigned to the field facet mirror 22, the manipulators 28-2 and 28-3 are also in each case configured as an adjustment device that allows a plurality of rigid body degrees of freedom, for example all six rigid body degrees of freedom, i.e. translations and rotations with respect to all three orthogonal spatial directions in each case, to be set. In this context, the adjustment devices may be manually adjustable or else comprise electrically controllable actuators.

As mentioned above, the mask 40 is exposed multiple times, with the mask structures 42 being imaged in each case onto the fields 64 of a multiplicity of semiconductor substrates 52. During the period of time used to this end, the illumination system 20 is operated in at least two different illumination settings, a first illumination setting 62a and a second illumination setting 62b in the exemplary embodiment according to FIG. 3. In this case, the exposure starts with, for instance, the first illumination setting 62a, in which only the radiation channels 35-30, 35-15, 35-28, 35-22, 35-24 and 35-5 are used, as described above.

On account of this very inhomogeneous illumination of the illumination beam path 34 and hence also of the imaging beam path 48 in the projection lens 50, thermal heating of the relevant optical elements in the projection lens 50 and the resultant surface modifications on the optical elements may lead to the formation of wavefront errors in the projection lens 50. In order to prevent this, the illumination is switched to the second illumination setting 62b after a certain duration of exposure operation, e.g. after the exposure of one or more batches of semiconductor substrates 52 or even after the exposure of a few semiconductor substrates 52 in a batch or after the exposure of a few fields 64 on a semiconductor substrate 52. After a certain further duration of exposure operation, before wavefront errors may likewise form due to heating of the relevant optical elements on account of the new radiation signature in the imaging beam path 48, the illumination setting may be set back to the first illumination setting 62a again. This cycle may be implemented multiple times.

In the second illumination setting 62b, the pupil plane 31 is illuminated with a second illumination distribution 60b. In this case, the exposure radiation 14 no longer irradiates the mirror elements 32-15, 32-30, 32-28, 32-22, 32-24 and 32-5, like in the illumination distribution 60a, but irradiates the mirror elements 32-16, 32-29, 32-14, 32-23, 32-4 and 32-6 instead. The pupil surface illuminated in the first illumination setting 62a, which corresponds to the totality of the surfaces 32o of the mirror elements 32-15, 32-30, 32-28, 32-22, 32-24 and 32-5, does not have any overlap with the pupil surface illuminated in the second illumination setting 62b, which corresponds to the totality of the surfaces of the mirror elements 32-15, 32-30, 32-28, 32-22, 32-24 and 32-5.

Hence, only the radiation channels 35-16, 35-29, 35-14, 35-23, 35-4 and 35-6 are used in the second illumination setting 62b, and hence are completely different radiation channels from the ones used in the first illumination setting 62a. The signature of thermal heating arising in the relevant optical elements in the projection lens 50 in the second illumination setting 62b is therefore so different from the signature arising in the first illumination setting 62a that surface modifications at the optical elements of the projection lens 50, which are starting to form on account of the signature of the first illumination setting 62a and which may cause wavefront errors, do not become any larger but possibly even reduce in size.

The signature of the second illumination setting 62b may naturally cause other surface modifications at the optical elements of the projection lens 50, which may likewise lead to wavefront errors. Therefore, the operation in the second illumination setting 62b is converted back to the operation in the first illumination setting 62a, optionally after the aforementioned, certain further duration that is short enough that these wavefront errors likewise cannot form to an extent where they become bothersome.

According to an embodiment depicted in FIG. 4, the switchover from the first illumination setting 62a to the second illumination setting 62b may be implemented incrementally. In the process, the illumination of a mirror element 32 or of a group of mirror elements 32 is switched over to another mirror element 32 or another group of mirror elements 32 in each step. To this end, two of the mirror elements 24-1, 24-3, 24-4, 24-6, 24-7 and 24-9 of the field facet mirror 22 are in each case switched in succession between different radiation channels 35.

In other words, a respective illumination of a surface portion or a subgroup of the surface portions in a first configuration, defined by the first illumination setting 62a, of surface portions in the pupil plane 31 is incrementally switched over to an illumination of a different surface portion or a different subgroup of the surface portions in a second configuration, defined by the second illumination setting 62b, of surface portions in the pupil plane 31. This incremental switchover may also be referred to as morphing. Specifically, in the embodiment according to FIG. 4, the transition from the first illumination distribution 60a according to FIG. 3 to the second illumination distribution 60b according to FIG. 3 is implemented in three steps.

In this case, there is a transition in a first step from the illumination distribution 60a to a first intermediate illumination distribution 60z1 by switching over the respective illumination of the mirror elements 32-30 and 32-22 to the mirror elements 32-16 and 32-4. This is implemented by appropriate tilting of the mirror elements 24-1 and 24-3. In a second step, there is a transition from the first intermediate illumination distribution 60z1 to a second intermediate illumination distribution 60z2 by switching over the respective illumination of the mirror elements 32-15 and 32-5 to the mirror elements 32-29 and 32-23. This is implemented by appropriate tilting of the mirror elements 24-4 and 24-6. In a third step, there is a transition from the second intermediate illumination distribution 60z2 to the second illumination distribution 60b by switching over the respective illumination of the mirror elements 32-28 and 32-24 to the mirror elements 32-14 and 32-6. This is implemented by appropriate tilting of the mirror elements 24-7 and 24-9.

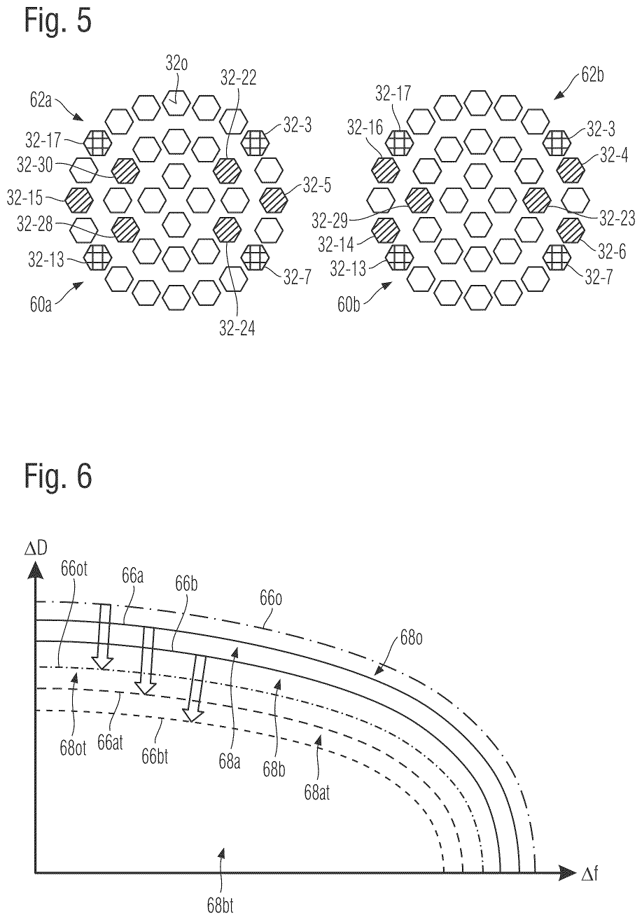

FIG. 5 shows an embodiment, in which the pupil surface illuminated in the first illumination setting 62a has a certain amount of overlap with the pupil surface illuminated in the second illumination distribution 62b. The pupil surface illuminated in the first illumination setting 62a corresponds to the totality of the surfaces of the mirror elements 32-17, 32-30, 32-15, 32-28, 32-13, 32-3, 32-22, 32-5, 32-24 and 32-7. The pupil surface illuminated in the second illumination setting 62b corresponds to the totality of the surfaces 32o of the mirror elements 32-17, 32-16, 32-29, 32-14, 32-13, 32-3, 32-4, 32-23, 32-6 and 32-7. The overlap between the illumination distributions 62a and 62b relates to the surfaces of the mirror elements 32-17, 32-13, 32-3 and 32-7, and hence relates to in each case four of the ten mirror elements illuminated in each case. Hence, the overlap is approximately 40% of the pupil surface illuminated in each case. According to further embodiments, the overlap may make up a lesser percentage or a greater percentage but may be a maximum of 90% of the pupil surface illuminated in each case. Since at least a proportion of the pupil surface is no longer illuminated when switching over between the two illumination settings 62a and 62b, the effects described above with reference to the embodiment according to FIG. 3 arise, and these may lead to the case where wavefront errors cannot form or can only form to a less pronounced extent.

The illumination distributions 60a, 60b and optionally 60z1 and 60z2 in the pupil plane 31 illustrated in FIGS. 3, 4 and 5 correspond according to one embodiment variant to the respective angular distributions of the exposure radiation 14 irradiating the various illuminated field points 43 on the mask 40. According to another embodiment variant, the angular distribution varies slightly from field point 43 to field point 43; in this case, the illumination distributions 60a, 60b and optionally 60z1 and 60z2 illustrated in FIGS. 3, 4 and 5 at least refer to one uniform field point 43, i.e. the same field point or a plurality of same field points in each case.

According to an embodiment variant, respective illumination distributions are assigned in the individual illumination settings 62a and 62b to a plurality of field points 43, which for example form a contiguous region 45 in the mask plane 44 (cf. FIG. 1), the illumination distributions either corresponding to those depicted in FIGS. 3, 4 and 5 or in each case deviating therefrom by a maximum of 5%, for example by a maximum of 1%. In other words, according to this embodiment variant, the illumination distributions 60a and 60b, described for the respective illumination settings 62a and 62b, in the pupil plane are present for the field points 43 arranged in the contiguous region 45, wherein the illumination distributions 60a and 60b are still referred to as the same illumination distribution even in the event of a pupil surface deviating by a maximum of 5%.

FIG. 6 illustrates lithographic process windows for a predetermined mask structure 42 under different illumination settings. These process windows are in each case represented by an area in a diagram, in which a defocus Δf of the imaging of the mask structure 42 in the image plane 53 is plotted against a dose variation ΔD of the exposure radiation 14 created by the exposure radiation source 12. The aforementioned area is formed by that region in the Δf-AD-diagram that is bounded by a process window curve 66 and the Δf- and ΔD-coordinate axes in the diagram. At all points of the process window represented by the area, a lithographic parameter is located within a tolerance range about a target value. For example, the lithographic parameter may be a variation of a critical dimension, for instance a line width in the photoresist (also referred to as CD variation), of the mask structure 42 imaged onto the semiconductor substrate 52 using the relevant illumination setting.

FIG. 6 depicts an optimized process window 68o for the aforementioned predetermined mask structure 42 using a process window curve 66o in the form of a dash-dotted line. That is to say, the process window 68o is based on an illumination distribution in the pupil plane 31, in which the area of the process window 68o is maximized while maintaining the proportions of the process window 68o. However, this process window 68o has this size only at the start of an exposure process, for as long as thermal heating effects do not yet play a substantial role in the projection lens 50. After a certain time of exposure operation, however, thermal heating effects lead to wavefront aberrations, which are also referred to as thermal wavefront aberrations in this text. These wavefront aberrations lead to the process window curve 66o being displaced to smaller ΔD and Δf values (see the process window curve 66ot), and hence the process window 68o is reduced to a correspondingly reduced-size process window 68ot.

In one exemplary embodiment, the illumination distributions 60a and 60b in the illumination settings 62a and 62b are in each case chosen in such a way that the respective areas of the associated process windows 68a and 68b, which arise without consideration of thermal wavefront aberrations, are in each case smaller than the area of the optimized process window 68o by no more than 10%, for example no more than 20%. The process windows 68a and 68b are in each case defined by the process window curves 66a and 66b. According to an embodiment variant, the respective areas of the process windows 68a and 68b are in each case at least 5% smaller than the area of the optimized process window 68o.

Although the process windows 68a and 68b are in each case smaller than the optimized process window 68o, they are larger than the process window 68ot that sets in after a certain amount of time on account of thermal wavefront aberrations. In the event of a relatively long exposure operation of the projection exposure apparatus 10 in one of the illumination distributions 60a and 60b, the corresponding process window would also reduce in size, to be precise the process window 68a would reduce to a process window 68at defined by a process window curve 66at, and the process window 68b would reduce to a process window 68bt defined by a process window curve 66bt. However, as explained above, this is prevented by virtue of switching back and forth between the illumination settings 60a and 60b before thermal wavefront aberrations may form.

Hence, use of the illumination settings 62a and 62b with the process windows 60a and 60b may permanently ensure a larger process window than in the event of a continual use of an illumination setting assigned to the optimized process window 68o.

According to a further exemplary embodiment, one of the two illumination settings 60a and 60b may be configured to create the optimized process window 68o, and the other illumination setting may correspond to a process window that is smaller than the process window 68a or the process window 68b.

The above description of exemplary embodiments, embodiments or embodiment variants should be understood to be by way of example. The disclosure effected thereby firstly enables the person skilled in the art to understand the present disclosure and the advantages associated therewith, and secondly encompasses alterations and modifications of the described structures and methods that are also obvious in the understanding of the person skilled in the art. Therefore, all such alterations and modifications, insofar as they fall within the scope of the disclosure in accordance with the definition in the accompanying claims, and equivalents are intended to be covered by the protection of the claims.

### LIST OF REFERENCE SIGNS

10 Projection exposure apparatus
12 Exposure radiation source
14 Exposure radiation
16 Input wave
18 Source point
20 Illumination system
22 Field facet mirror
23 Field plane
24, 24-1 to 24-9 Mirror elements
26 Sectional line
28-1 Manipulator of the field facet mirror
28-2 Manipulator of the pupil facet mirror
28-3 Manipulator of the G-mirror
28-4 Manipulator of the mirror elements of the field facet mirror
29-1 to 29-3 Frame elements
30 Pupil facet mirror
31 Pupil plane
32, 32-1 to 32-32 Mirror elements
32o Surface of a mirror element
33 Sectional line
34 Illumination beam path
35-1 to 35-32 Radiation channels
36 G-mirror
36a Mirror surface
38 Output wave
39 Individual ray
40 Mask
41 System surface
42 Mask structures
42P Point on the mask surface
43 Field points
44 Mask plane
45 Contiguous region in the mask plane
46 Illumination field
48 Imaging beam path
50 Projection lens
52 Semiconductor substrate
53 Image plane
54 Substrate stage
58 Incoming radiation direction
60a First illumination distribution in the pupil plane
60b Second illumination distribution in the pupil plane
60z1 First intermediate illumination distribution
60z2 Second intermediate illumination distribution
62a First illumination setting
62b Second illumination setting
64 Field on the semiconductor substrate
66a Process window curve
66at Process window curve with thermal aberrations
66b Process window curve
66bt Process window curve with thermal aberrations
66o Optimized process window curve
66ot Optimized process window curve with thermal aberrations
68a Process window
68at Process window with thermal aberrations
68b Process window
68bt Process window with thermal aberrations
68o Optimized process window
68ot Optimized process window with thermal aberrations

What is claimed is:

1. A method of operating a microlithographic projection exposure apparatus comprising an illumination system, the method comprising:
repeatedly exposing a mask to exposure radiation provided by the illumination system; and
in each exposure, imaging mask structures on one of a multiplicity of fields of a plurality of semiconductor substrates,
wherein the method comprises:
during a period in which the repeated exposure of the mask takes place, successively using the illumination system in first and second illumination settings of the illumination system, the first illumination setting having a first illumination distribution of the exposure radiation in a pupil plane of the illumination system, the second illumination setting having a second illumination distribution of the exposure radiation in the pupil plane of the illumination system, the second illumination distribution setting being different from the first illumination setting so that: i) a pupil surface illuminated in the first illumination setting has no overlap with a pupil surface illuminated in the second illumination setting; or ii) a pupil surface illuminated in the first illumination setting has an overlap of a maximum of 90% of a pupil surface illuminated in the second illumination setting; and
fully exposing the mask at least once in each of the two different illumination settings.

2. The method of claim 1, wherein switching between the first and second illumination settings, there is a time interval of less than 200 minutes.

3. The method of claim 1, wherein each of the pupil surfaces illuminated in the first and second illuminations comprises a plurality of surface portions that are separated from one another.

4. The method of claim 3, wherein switching from the first illumination setting to the second illumination setting comprises incrementally switching the illumination distribution in the pupil plan from the distribution of the first illumination setting to the distribution of the second illumination setting.

5. The method of claim 1, wherein switching from the first illumination setting to the second illumination setting comprises incrementally adapting the first illumination distribution to the second illumination distribution.

6. The method of claim 5, wherein:
the illumination system comprises a pupil facet optical unit which comprises a plurality of individual optical units arranged in a pupil plane of the illumination system;
the illumination system comprises a field facet optical unit arranged in a plane conjugate to a mask plane in which the mask is disposed;
the field facet optical unit comprises a plurality of further individual optical units configured to irradiate the individual optical units of the pupil facet optical unit for the respective formation of a radiation channel of the beam path of the illumination radiation; and
the incremental adaptation of the first illumination distribution to the second illumination distribution comprises switching between different radiation channels by successively moving one or more of the individual optical units of the field facet optical unit.

7. The method of claim 1, wherein each of the first and second illumination distributions is assigned to at least one uniform field point in a mask plane in which the mask is disposed.

8. The method of claim 1, wherein, in either of the first and second illumination settings, an illumination distribution or an illumination distribution with a deviation of no more than 5% is assigned to a plurality of field points in the mask plane.

9. The method of claim 8, wherein the plurality of field points form a contiguous region in the mask plane.

10. The method of claim 1, wherein:
in each of the first and second illumination settings, an area of a lithographic process window for imaging a predetermined type of mask structures is no more than 20% smaller than an area of an assigned optimized lithographic process window;
the area of a lithographic process window for imaging the predetermined type of mask structures does not take into account thermal wavefront aberrations that are due to thermal heating effects in a projection lens of the projection exposure apparatus caused by the exposure radiation; and
the area of the assigned optimized lithographic process window is optimized for imaging the given type of mask structures by varying the illumination setting.

11. The method of claim 10, wherein, in one of the first and second illumination settings, the area of the lithographic process window is optimized for imaging a predetermined type of mask structures without taking into account the thermal wavefront aberrations.

12. The method of claim 10, wherein, in at least one of the first and second illumination settings, the area of the lithographic process window for imaging a predetermined type of mask structures without taking into account the thermal wavefront aberrations is at least 5% smaller than the area of the assigned optimized process window.

13. The method of claim 1, wherein, in a configuration of the mask structures and the illumination distribution of at least one of the first and second illumination settings, thermal heating effects in a projection lens of the projection exposure apparatus, which occur within a period of time in which the mask is exposed with the respective illumination setting, are taken into account.

14. The method of claim 1, wherein the exposure radiation is in the EUV wavelength range.

15. A method of operating a microlithographic projection exposure apparatus comprising an illumination system, the method comprising:
a) fully exposing a mask to exposure radiation provided by the illumination system in a first illumination setting;
b) during a), imaging mask structures on one of a multiplicity of fields of a plurality of semiconductor substrates;
c) after b), fully exposing the mask to exposure radiation provided by the illumination system in a second illumination setting; and
d) during d), imaging mask structures on one of a multiplicity of fields of the plurality of semiconductor substrates,
wherein:
the first illumination setting has a first illumination distribution of the exposure radiation in a pupil plane of the illumination system;
the second illumination setting has a second illumination distribution of the exposure radiation in the pupil plane of the illumination system; and
the second illumination distribution setting is different from the first illumination setting so that: i) a pupil surface illuminated in the first illumination setting has no overlap with a pupil surface illuminated in the second illumination setting; or ii) a pupil surface illuminated in the first illumination setting has an overlap of a maximum of 90% of a pupil surface illuminated in the second illumination setting.

16. The method of claim 15, wherein switching between the first and second illumination settings, there is a time interval of less than 200 minutes.

17. The method of claim 15, wherein each of the pupil surfaces illuminated in the first and second illuminations comprises a plurality of surface portions that are separated from one another.

18. The method of claim 15, wherein switching from the first illumination setting to the second illumination setting comprises incrementally adapting the first illumination distribution to the second illumination distribution.

19. The method of claim 15, wherein each of the first and second illumination distributions is assigned to at least one uniform field point in a mask plane in which the mask is disposed.

20. The method of claim 15, wherein, in either of the first and second illumination settings, an illumination distribution or an illumination distribution with a deviation of no more than 5% is assigned to a plurality of field points in the mask plane.
